(19) United States
(12) Patent Application Publication
(10) Pub. No.: US 2005/0221557 A1
(43) Pub. Date: Oct. 6, 2005

(54) Method for producing a deep trench capacitor in a semiconductor substrate

(75) Inventors: Steve Wang, Dresden (DE); Kae-Horng Wang, Dresden (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munchen (DE)

(21) Appl. No.: 10/812,412

(22) Filed: Mar. 30, 2004

(51) Int. Cl. H01L 21/8242

(52) U.S. Cl. 438/243

(57) ABSTRACT

The present invention provides a method for producing a deep trench capacitor in a semiconductor substrate (1) comprising the steps of: providing a first trench (2) in the semiconductor substrate (1); oxidizing the semiconductor substrate (1) in the first trench (2) for providing an oxidized silicon layer (3); depositing a conformal aluminium-oxide layer (4) in the first trench (2); removing the horizontal regions (5) of the deposited aluminium-oxide layer (4) and the oxidized silicon layer (3); providing a second trench (6) underneath the first trench (2); increasing the width of the second trench (6) to a widened second trench (7) for providing a bottle structure (8); depositing a dielectric layer (10) in the widened second trench (7) and filling the widened second trench (7) with a conductive filling (11).

The present invention relates to a method for producing a deep trench capacitor in a semiconductor substrate.

Although applicable in principle to any desired integrated circuits, the present invention and the problem area on which it is based are explained with regard to integrated memory circuits in silicon technology.

Integrated circuits (ICs) or chips use capacitors for the purpose of storing charge. One example of an IC which uses capacitors to store charges is a memory IC, such as e.g. a chip for a dynamic random access memory (DRAM). The charge state (“0” or “1”) in the capacitor represents a data bit in this case.

A DRAM memory cell usually contains a transistor connected to a capacitor. The transistor contains two diffusion regions separated by a channel above which a gate is arranged. Depending on the direction of the current flow, one diffusion region is referred to as the drain, and the other as the source. The gates are connected to a word line, and one of the diffusion regions is connected to a bit line. The other diffusion region is connected to the capacitor. The application of a suitable voltage to the gate switches the transistor on and enables a current flow between the diffusion regions through the channel in order to form a connection between the capacitor and the bit line. The switching-off of the transistor disconnects this connection by interrupting the current flow through the channel.

The charge stored in the capacitor decreases with time on account of an inherent leakage current. Before the charge has decreased to an indefinite level (below a threshold value), the storage capacitor must be refreshed.

Continuous efforts to reduce the size of storage devices have led to the design of DRAMs having a greater density and a smaller characteristic size, that is to say a smaller memory cell area. In order to produce memory cells that occupy a smaller surface region, smaller components, e.g. capacitors, are used. However, the use of smaller capacitors results in a reduced storage capacitance which, in turn, can adversely affect the functionality and usability of the storage device. For example, sense amplifiers require a sufficient signal level for a reliable read-out of the information in the memory cells. The ratio of the storage capacitance to the bit line capacitance is critical in determining the signal level. If the storage capacitance becomes too small, this ratio may be too small to generate a sufficient signal. Likewise, a smaller storage capacitance requires a high refresh frequency.

One type of capacitor usually used in DRAMs is a trench capacitor. A trench capacitor has a three-dimensional structure formed in the silicon substrate. An increase in the volume or the capacitance of the trench capacitor can be achieved by etching more deeply into the substrate. In this case, the increase in the capacitance of the trench capacitor does not have the effect of enlarging the surface occupied by the memory cell.

A customary trench capacitor contains a trench etched into the substrate. This trench is typically filled with p⁺- or n⁺-doped polysilicon which serves as one capacitor electrode (also referred to as storage capacitor). The second capacitor electrode is the substrate or a “buried plate”. A capacitor dielectric containing e.g. nitride is usually used to insulate the two capacitor electrodes.

A dielectric layer (preferably an oxide region) is produced in the upper region of the trench in order to prevent a leakage current or to insulate the upper part of the capacitor.

In general the trench capacitor lies underneath other structures of the DRAM. To process the capacitor a process window through the other structures is needed, whereas the sidewalls of the process window have to be shielded by a shielding layer against the process steps for producing the capacitor.

The capacitance of the capacitor is depended from the volume of the capacitor. At a predetermined width respectively process window on which the integration degree of the semiconductor is depended, the depth of the capacitor in the substrate has to be increased. To make sure that the process window is as wide as possible for ensuring a high aspect ratio, the shielding layer has to be of minimal thinness and maximal conformity.

What has been of great interest recently is increasing the aspect ratio of the deep trench capacitor to be precise particularly if the relevant trench capacitor is used for producing a semiconductor memory. An increased aspect ratio for the trench in which the deep capacitor is built makes it possible to significantly increase the integration degree of the semiconductor structure.

Therefore, it is an object of the present invention to specify a method of producing a deep trench capacitor in a semiconductor substrate with an improved aspect ratio and improved capacitance.

According to the invention, this object is achieved by means of a method for producing a deep trench capacitor in a semiconductor substrate specified in claim 1.

Thereby, the method for producing a deep trench capacitor in a semiconductor substrate comprises the following steps: providing a first trench in the semiconductor substrate; oxidizing the semiconductor substrate in the first trench for providing an oxidized silicon layer; depositing a conformal aluminium-oxide layer in the first trench; removing the horizontal regions of the deposited aluminium-oxide layer and oxidized silicon layer; providing a second trench underneath the first trench; increasing the width of the second trench to a widened second trench for providing a bottle structure; depositing a dielectric layer in the widened second trench and filling the widened second trench with a conductive filling.

The advantage of the method according to the invention is in particular the fact that depositing the conformal aluminium-oxide layer in the first trench for shielding the side walls of the first trench is achieved by a process which makes a very thin aluminium-oxide layer and which can be easily controlled. The very thin conformal aluminium-oxide layer provides a process window which is as wide as possible for processing the second trench underneath the first trench.

Therefore, the volume of the capacitor built in the deep second widened trench is increased which follows a higher capacitance of the capacitor. The increase in the capacitance of the trench capacitor does not enlarge the surface occupied by the memory cell. Thus at a predetermined integration degree the capacitance of the capacitor can be increased or at a predetermined capacitance the integration degree of the memory cell can be increased.

Further the semiconductor substrate can be used as a first electrode for the capacitor, if the semiconductor substrate is high doped.

Advantages, developments and improvements of the method according to the invention are found in the subclaims.

In accordance with a preferred development, after the step of increasing the width of the second trench to the widened second trench a doping the semiconductor substrate in the widened second trench is provided for providing or improving the first electrode. Then the first electrode is formed as a buried plate.

In accordance with a further preferred development, the following step is provided after the step of increasing the width of the second trench to the widened second trench or after doping the semiconductor substrate in the widened second trench: depositing a rugged polysilicon layer in the widened second trench.

An advantage of this preferred development is that the deposited rugged polysilicon layer increases the capacitance of the deep capacitor.

In accordance with a further preferred development, the depositing of the rugged polysilicon layer in the widened second trench is provided by a hemispherical grain (HSG) polysilicon deposition process.

In accordance with a further preferred development, the depositing of the dielectric layer in the widened second trench is provided by means of the following steps: depositing a first silicon nitride layer and oxidation of the first silicon nitride layer for providing the dielectric layer.

In accordance with a further preferred development, the conductive filling is a polysilicon filling.

In accordance with a further preferred development, the aluminium layer is an Al₂O₃-layer.

In accordance with a further preferred development, the step of increasing the width of the second trench to the widened second trench for providing the bottle structure is provided by a wet etching process.

In accordance with a further preferred development, the step of increasing the width of the second trench to the widened second trench for providing the bottle structure is provided by a reactive ion etching process (RIE).

Exemplary embodiments of the invention are illustrated in the drawings and explained in more detail in the description below.

In the Figures:

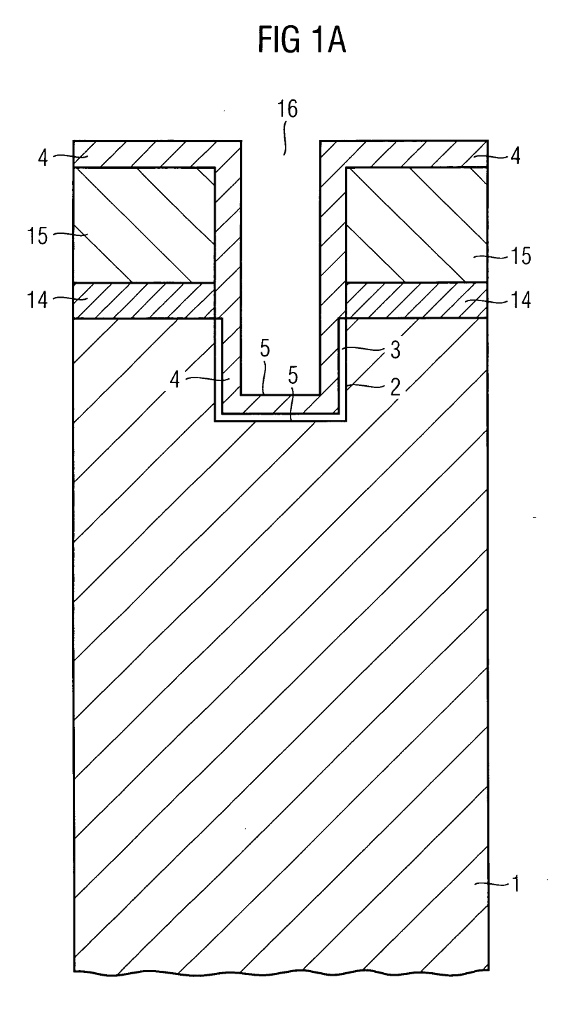

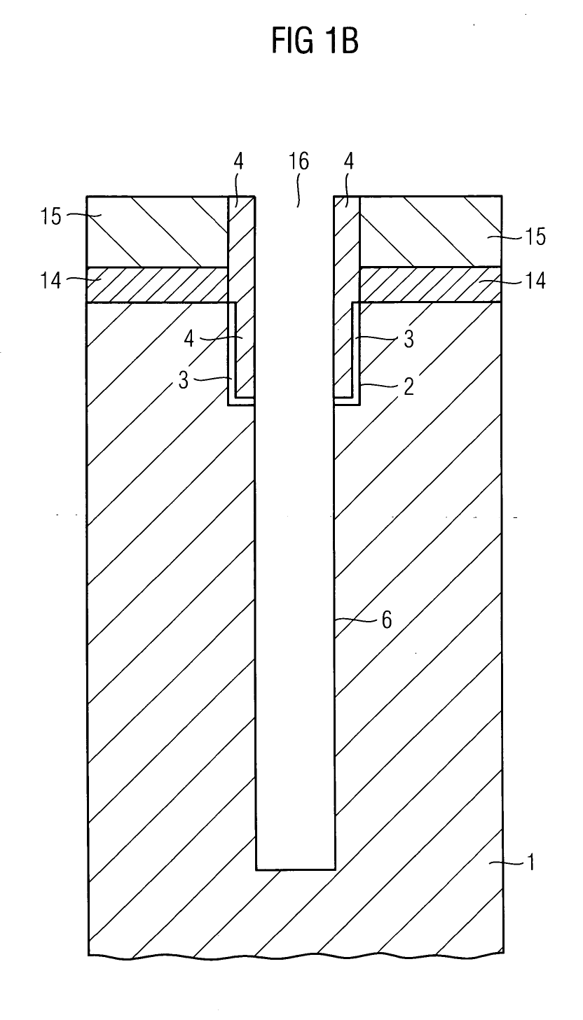

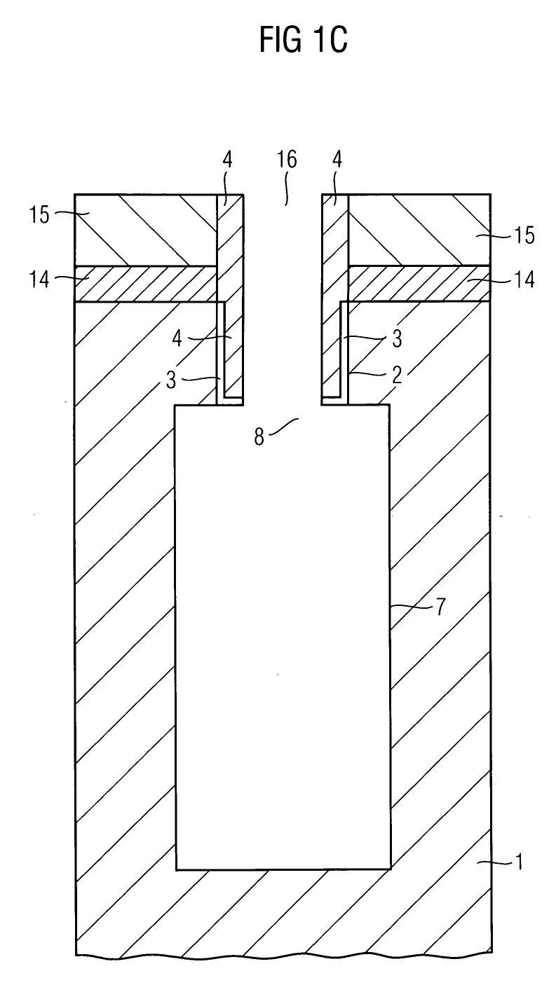

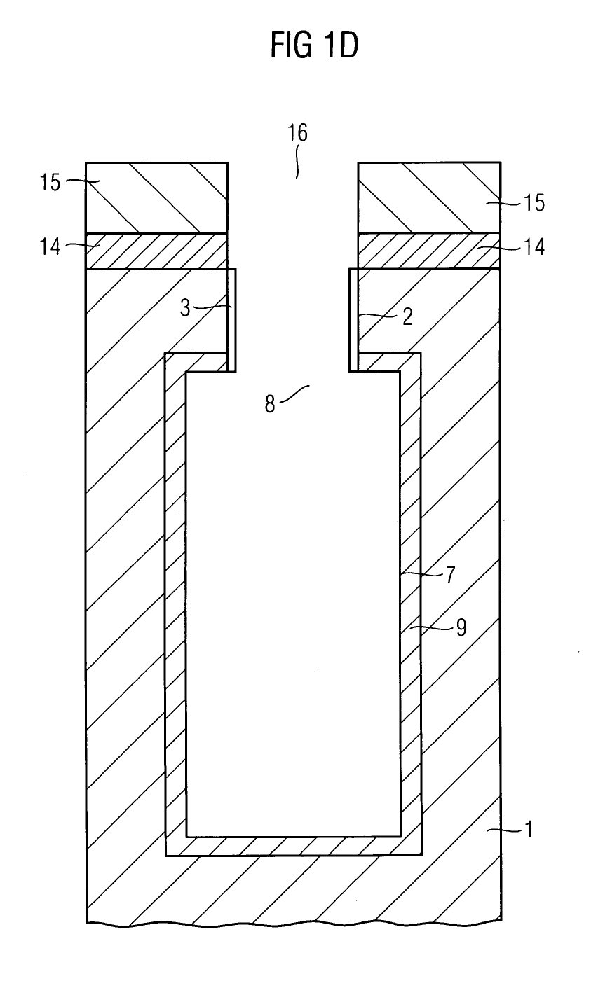

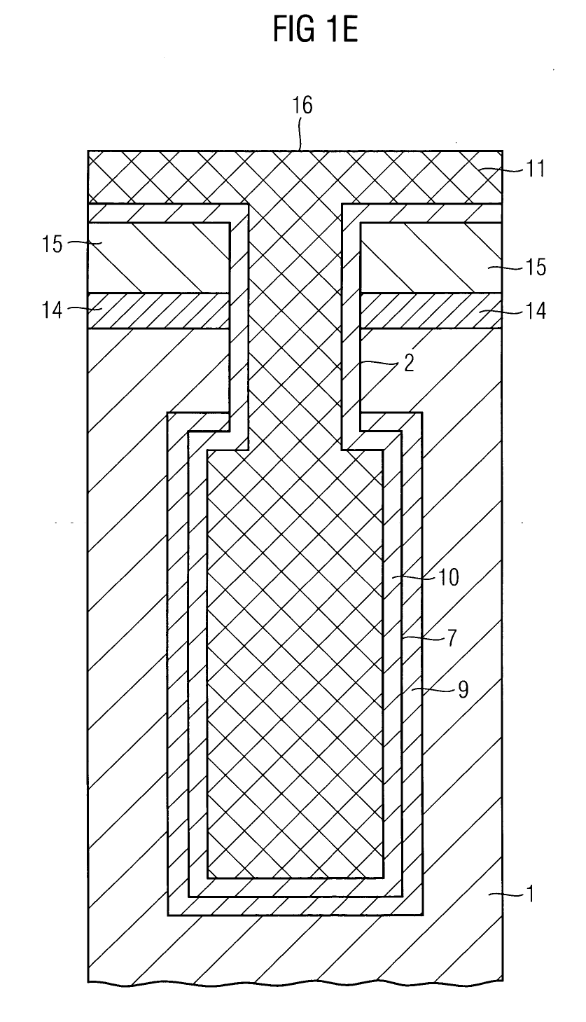

FIGS. 1a-e show schematical views of successive method steps of a method for producing a deep trench capacitor in a semiconductor substrate as a first embodiment according to the invention;

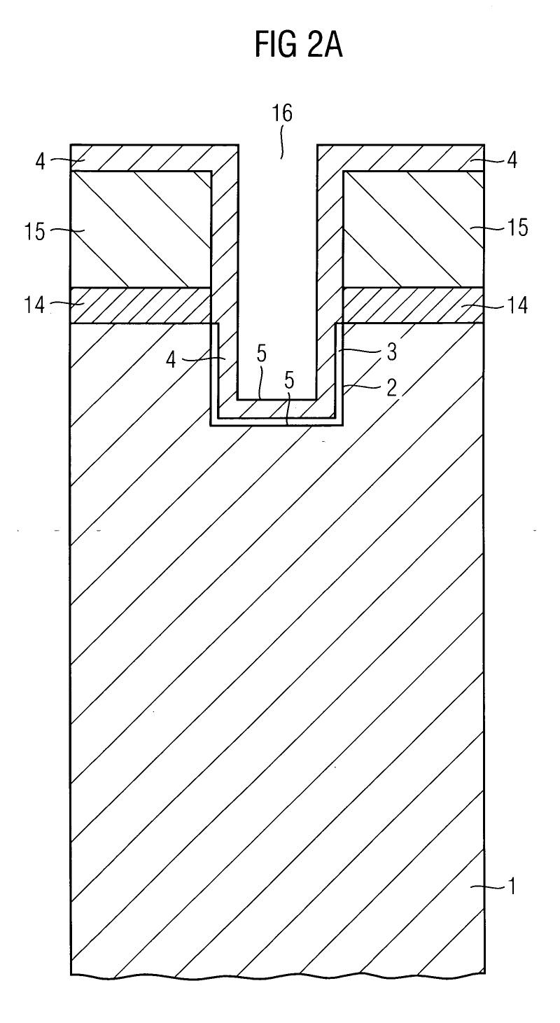

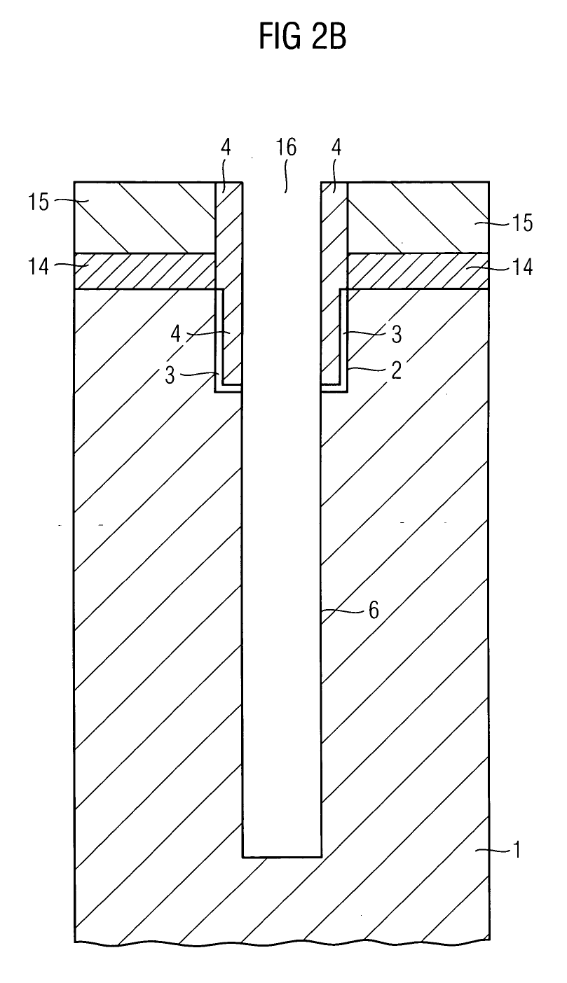

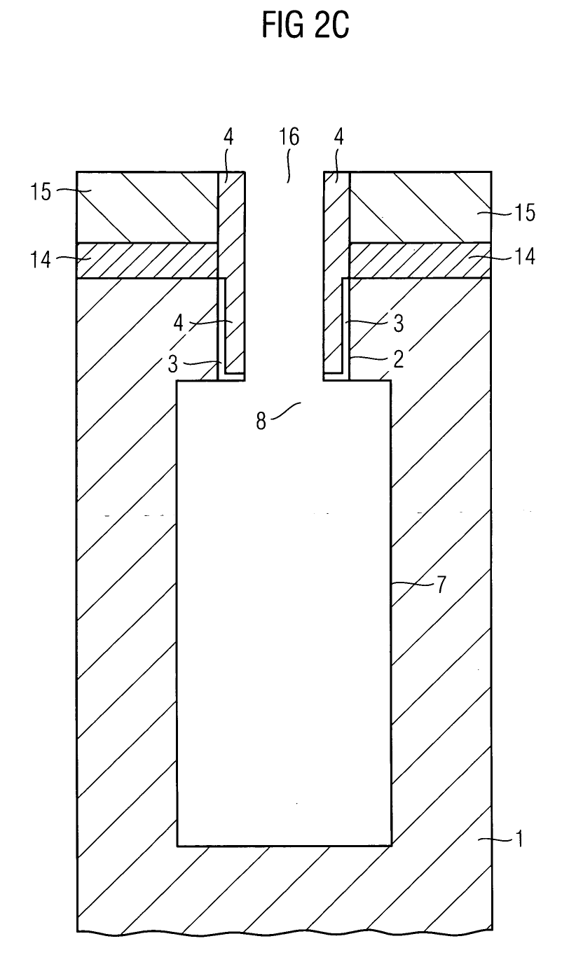

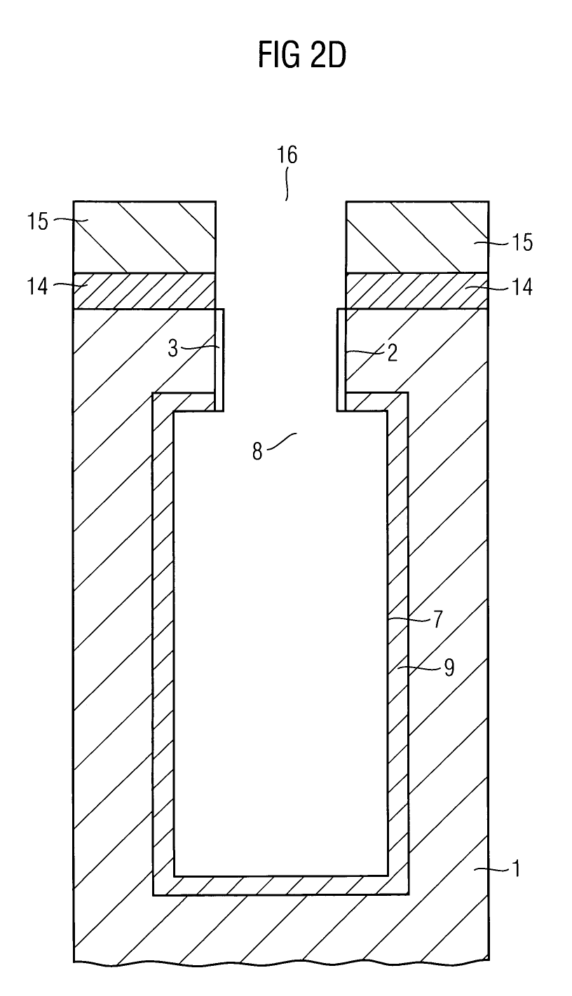

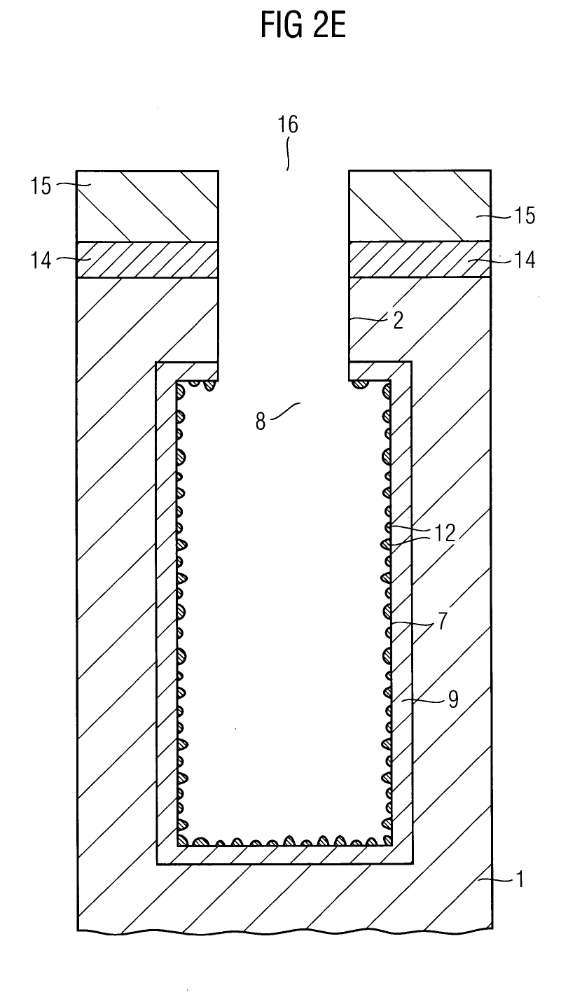

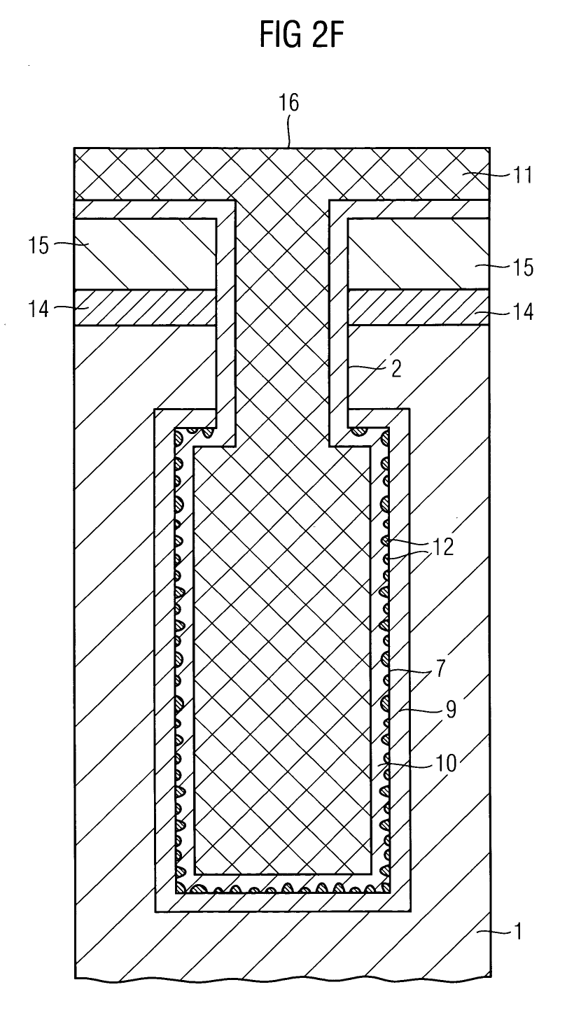

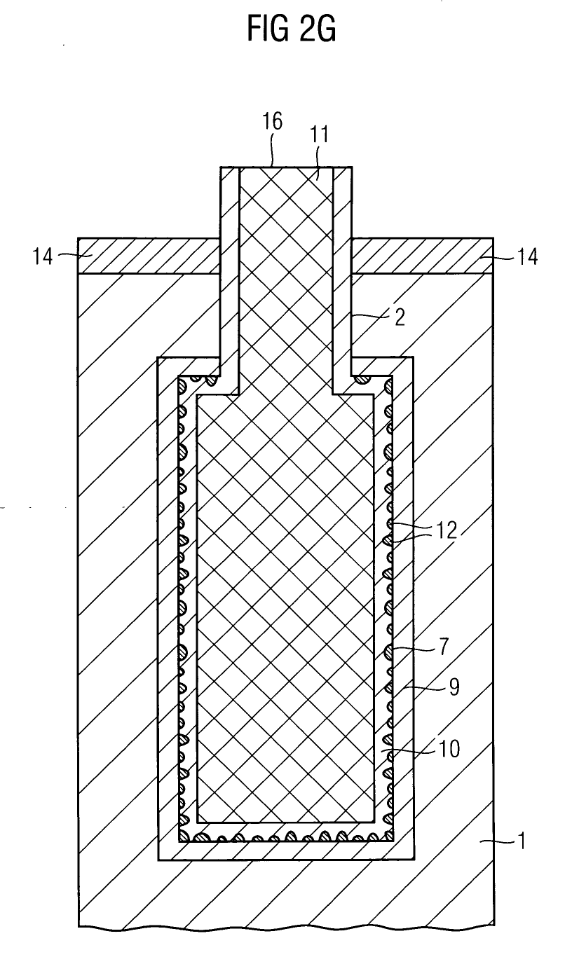

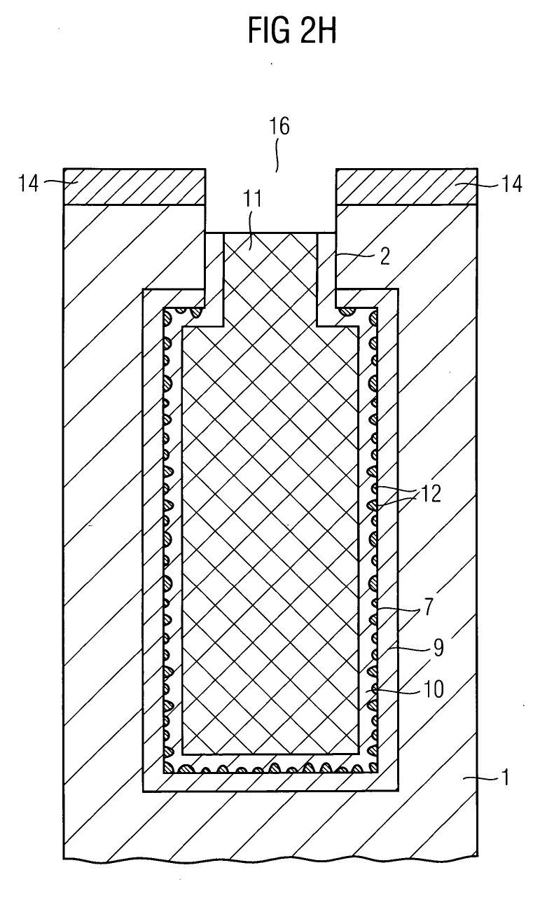

FIGS. 2a-h show schematical views of successive method steps of a method for producing a deep trench capacitor in a semiconductor substrate as a second embodiment according to the invention.

In the Figures, identical reference symbols designate identical or functionally identical elements.

FIG. 1a-e are schematical views of successive method steps of a method for producing a deep trench capacitor in a semiconductor substrate as a first embodiment according to the invention.

In FIG. 1a, reference symbol 1 designates the semiconductor substrate. On the top side of the semiconductor substrate 1, a silicon nitride layer 14 is provided. On the top side of the silicon nitride layer 14, a hardmask 15 is provided.

By means of a deep trench mask open process (DTMO), a process window 16 is provided through the hardmask 15 and the silicon nitride layer 14. By means of the process window 16, a first trench 2 is provided in the silicon semiconductor substrate 1.

The semiconductor substrate 1 in the first trench 2 is oxidized for providing an oxidized silicon layer 3.

After that, a conformal and thin aluminium-oxide layer 4, preferably Al₂O₃, is deposited in the first trench 2.

Afterwards, with reference to FIG. 1b, the removal of horizontal regions 5 of the deposited aluminium-oxide layer 4 and the oxidized silicon layer 3 follows by means of a liner opening process. After that, an etching process follows to provide a second trench 6 underneath the first trench 2. Because of these etching processes also a upper region of the hardmask 15 is consumed.

Afterwards, with reference to FIG. 1c, an increase of the width of the second trench 6 to a widened second trench 7 follows for providing a bottle structure 8, so that the bottle structure 8 is shaped through first trench 2 and widened second trench 7.

Preferably, the widening of the second trench 6 to the widened second trench 7 is provided by means of a wet etching process or a reactive ion etching process (RIE).

Afterwards, with reference to FIG. 1d, the semiconductor substrate 1 in the widened second trench 7 is doped for providing a first electrode 9.

Preferably, the semiconductor substrate 1 is doped with arsenic.

After that, the aluminium-oxide layer 4 in the first trench 2 is removed.

Afterwards, with reference to FIG. 1e, the oxidized silicon layer 3 in the first trench 2 is removed. A dielectric layer 10 is deposited in the trenches 2 and 7.

After that, the deep trench consisting of the first trench 2 and the widened second trench 7 is filled with a conductive filling 11 for finalizing the deep trench capacitor.

FIG. 2a-h are schematical views of successive method steps of a method for producing a deep trench capacitor in a semiconductor substrate as a second embodiment according to the invention.

FIG. 2a-d correspond to FIG. 1a-d. After producing the structure according to FIG. 1d or FIG. 2d respectively, and the oxidized silicon layer 3 in the first trench 2 is removed a rugged polysilicon layer 12 is deposited in the widened second trench 7 with reference to FIG. 2e.

Afterwards, with reference to FIG. 2f, the dielectric layer 10 is deposited in the widened second trench 7. After that, the widened second trench 7 is filled with a conductive filling 11, preferably polysilicon.

Afterwards, with reference to FIG. 2g, a removal of polysilicon layer 16 and dielectric layer 10 on top of the hardmask 15, preferably silicon oxide, and a removal of the hardmask 15 are performed.

Afterwards, with reference to FIG. 2h, an etching process follows to etch back the conductive filling 11 and the dielectric layer 10 in the upper region of first trench 2 for finalizing the deep trench capacitor.

Although the present invention has been described above on the basis of preferred exemplary embodiments, it is not restricted thereto, but can rather be modified in diverse ways.

In particular, the selection of the layer materials is made only by way of example and can be varied in many different ways.

1. A method for producing a deep trench capacitor in a semiconductor substrate, comprising:
providing a first trench in the semiconductor substrate;
oxidizing the semiconductor substrate in the first trench for providing an oxidized silicon layer;
depositing a conformal aluminium-oxide layer in the first trench;
removing horizontal regions of the deposited aluminium-oxide layer and the oxidized silicon layer;
providing a second trench underneath the first trench;
increasing a width of the second trench to a widened second trench for providing a bottle structure;
depositing a dielectric layer in the widened second trench; and
filling the widened second trench with a conductive filling.

2. The method according to claim 1, wherein after increasing the width of the second trench to the widened second trench a doping the semiconductor substrate in the widened second trench is provided for providing a first electrode.

3. The method according to claim 1, wherein after increasing the width of the second trench to the widened second trench or after doping the semiconductor substrate in the widened second trench, further comprising:
depositing a rugged polysilicon layer in the widened second trench.

4. The method according to claim 3, wherein the depositing of the rugged polysilicon layer in the widened second trench is provided by a hemispherical grain polysilicon deposition process.

5. The method according to claim 1, wherein depositing a dielectric layer comprises:
depositing a first silicon nitride layer; and
oxidation the first silicon nitride layer for providing the dielectric layer.

6. The method according to claim 1, wherien the conductive filling is a polysilicon filling.

7. The method according to claim 1, wherein the aluminium-oxide layer is a Al₂O₃-layer.

8. The method according to claim 1, wherein increasing the width of the second trench to the widened second trench for providing the bottle structure is provided by a wet etching process.

9. The method according to claim 1, wherein the increasing the width of the second trench to the widened second trench for providing the bottle structure is provided by a reactive ion etching process.
